(19) United States
(12) Patent Application Publication
(10) Pub. No.: US 2009/0051444 A1
(43) Pub. Date: Feb. 26, 2009

(54) FREQUENCY-CORRECTED CLOCK SIGNAL GENERATION INTEGRATED CIRCUIT DEVICE

(75) Inventor: Katsumi INOUE, Nagoya-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/195,012

(22) Filed: Aug. 20, 2008

(30) Foreign Application Priority Data
Aug. 24, 2007 (JP) 2007-218246

(51) Int. Cl. H03L 1/00; H03K 3/03

(52) U.S. Cl. 331/57; 331/175; 331/176

(57) ABSTRACT

An integrated circuit device including: an oscillation circuit that generates a first clock signal; a frequency comparison section that compares a frequency of the first clock signal with a frequency of a second clock signal; and a clock signal generation section that generates a third clock signal based on the first clock signal. The clock signal generation section corrects a frequency of the third clock signal to be a value within a predetermined range based on the comparison result. For example, the frequency comparison section counts a predetermined period based on the first clock signal, the predetermined period being defined based on the second clock signal, and the clock signal generation section generates the third clock signal by dividing the frequency of the first clock signal based on the count result.

Japanese Patent Application No. 2007-218246, filed on Aug. 24, 2007, is hereby incorporated by reference in its entirety.

### BACKGROUND OF THE INTENTION

The present invention relates to a frequency-corrected clock signal generation integrated circuit device.

A smoke-detection IC used for fire alarm systems is continuously battery-driven for a long period of time (e.g., ten years). Therefore, the smoke-detection IC must operate with low power consumption. An IC for which low power consumption is desired utilizes an oscillation circuit (e.g., ring oscillator) that can generate a master clock signal at low cost with low power consumption. However, since the oscillation frequency of the oscillation circuit changes due to a change in environment (e.g., temperature), it is important to ensure that the oscillation frequency of the oscillation circuit is constant even if a change in temperature occurs.

For example, JP-A-11-338572 proposes a clock signal generator that compares a master clock signal with the output from an oscillator with high frequency accuracy, and feeds back the difference in frequency to a ring oscillator to control the oscillation frequency.

However, this method requires a complex feedback control circuit. Moreover, since it is necessary to supply the output from the oscillator to a frequency comparison circuit and the like until the master clock signal is stabilized due to feedback control, power consumption increases.

### SUMMARY

According to one aspect of the invention, there is provided an integrated circuit device comprising:

an oscillation circuit that generates a first clock signal;

a frequency comparison section that compares a frequency of the first clock signal with a frequency of a given second clock signal; and

a clock signal generation section that generates a third clock signal based on the first clock signal,

the clock signal generation section correcting a frequency of the third clock signal to be a value within a predetermined range based on the comparison result of the frequency comparison section.

### BRIEF DESCRIPTION OF THE SEVERAL VIEWS OF THE DRAWING

FIG. 1 is a functional block diagram showing an integrated circuit device (measurement system) according to one embodiment of the invention.

FIG. 2 is a diagram illustrative of a configuration example of an oscillation circuit.

FIG. 3A is a graph illustrative of an example of the temperature characteristics of a current that flows through a ring oscillator, FIG. 38 is a graph illustrative of an example of the temperature characteristics of a reference voltage output from a regulator, and FIG. 3C is a graph illustrative of an example of the temperature characteristics of the oscillation frequency of a ring oscillator.

FIG. 4 is a block diagram showing a fire alarm system according to one embodiment of the invention.

FIG. 5 is a timing chart illustrative of an example of the operation timing of an integrated circuit device (measurement system) according to one embodiment of the invention.

FIG. 6 is a timing chart illustrative of an example of the operation timing of a frequency measurement circuit and a timer.

### DETAILED DESCRIPTION OF THE EMBODIMENT

The invention may provide an integrated circuit device that has a simple configuration and consumes only a small amount of power by correcting the frequency of an operation clock signal generated from a master clock signal instead of correcting the frequency of the master clock signal by feedback control.

(1) According to one embodiment of the invention, there is provided an integrated circuit device comprising:

an oscillation circuit that generates a first clock signal;

a frequency comparison section that compares a frequency of the first clock signal with a frequency of a given second clock signal; and

a clock signal generation section that generates a third clock signal based on the first clock signal,

the clock signal generation section correcting a frequency of the third clock signal to be a value within a predetermined range based on the comparison result of the frequency comparison section.

The frequency comparison section may compare the frequency of the first clock signal with the frequency of the second clock signal either directly or indirectly. For example, the frequency comparison section may indirectly compare the frequency of the first clock signal with the frequency of the second clock signal by comparing the duration of a period defined based on the first clock signal with the duration of a period defined based on the second clock signal.

The clock signal generation section may correct the frequency of the third clock signal to be a frequency within a predetermined error range with respect to a target frequency based on the comparison result of the frequency comparison section.

The second clock signal may be supplied from the outside of the integrated circuit device, or may be generated in the integrated circuit device.

The second clock signal affects the correction accuracy of the frequency of the third clock signal. Therefore, it is preferable that the second clock signal has high frequency accuracy. It is more preferable that the frequency of the second clock signal change to only a small extent due to a change in environment (e.g., a change in temperature). The second clock signal may be a clock signal output from a crystal oscillator or a CR oscillation circuit, for example.

According to this embodiment, the frequency of the third clock signal generated based on the first clock signal output from the oscillation circuit is corrected based on the second clock signal. Therefore, even if the accuracy of the frequency of the first clock signal is low, the frequency of the third clock signal can be corrected with high accuracy when the accuracy of the frequency of the second clock signal is high.

According to this embodiment, the accuracy of the frequency of the third clock signal mainly depends on the accuracy of the frequency of the second clock signal, but depends on the accuracy of the frequency of the first clock signal to only a small extent. Therefore, the configuration of the oscillation circuit that generates the first clock signal can be simplified.

According to this embodiment, it is unnecessary to directly correct the frequency of the first clock signal output from the oscillation circuit. Therefore, it is unnecessary to provide a feedback control circuit for controlling the oscillation operation of the oscillation circuit.

(2) In this integrated circuit device,

the frequency comparison section may count a predetermined period based on the first clock signal, the predetermined period being defined based on the second clock signal; and

the clock signal generation section may generate the third clock signal by frequency-dividing the first clock signal based on a count result of the frequency comparison section.

The predetermined period may be directly counted based on the first clock signal, or may be counted based on the divided clock signal of the first clock signal, for example.

The predetermined period defined based on the second clock signal may be a period corresponding to one cycle or a half cycle of the second clock signal, or may be a period corresponding to one cycle or a half cycle of a divided clock signal of the second clock signal, for example.

A period corresponding to one cycle or a half cycle of the corrected third clock signal may be defined based on the second clock signal, for example.

For example, when the count result is n (n is an integer equal to or larger than one), the third clock signal may be generated by dividing the frequency of the first clock signal by a factor of n.

According to this embodiment, the number of cycles of the first clock signal corresponding to the predetermined period defined based on the second clock signal is counted directly or indirectly, and the third clock signal is generated based on the count result. Therefore, the frequency of the third clock signal can be corrected with the accuracy of the frequency of the second clock signal.

According to this embodiment, the predetermined period defined based on the second clock signal is counted based on the first clock signal. Therefore, even if the frequency of the second clock signal is higher than the frequency of the first clock signal, the predetermined period can be counted based on the first clock signal by setting the predetermined period to be longer than one cycle of the first clock signal.

According to this embodiment, the count value increases as the predetermined period defined based on the second clock signal increases. Therefore, the accuracy of the frequency of the third clock signal corrected based on the second clock signal can be improved.

According to this embodiment, the frequency of the third clock signal can be corrected by a simple configuration (i.e., counter circuit and frequency divider circuit).

(3) In this integrated circuit device, the frequency comparison section may intermittently compare the frequency of the first clock signal with the frequency of the second clock signal.

For example, the frequency comparison section may compare the frequency of the first clock signal with the frequency of the second clock signal each time a predetermined period of time has been counted based on the third clock signal (e.g., once an hour).

The frequency comparison section may intermittently compare the frequency of the first clock signal with the frequency of the second clock signal by intermittently counting the predetermined period defined based on the second clock signal based on the first clock signal. The frequency comparison section may hold the count result until the subsequent count operation is completed, and the clock signal generation section may generate the third clock signal based on the count result held by the frequency comparison section.

According to this embodiment, the frequency comparison section intermittently performs the comparison operation. Therefore, the number of comparison operations performed by the frequency comparison section can be reduced so that the supply of the second clock signal can be stopped when the comparison operation is not performed. As a result, current consumption can be significantly reduced. Therefore, the integrated circuit device can be battery-driven for a long time even if the frequency of the second clock signal is high.

(4) The integrated circuit device may further comprise:

a frequency control section that controls the frequency of the first clock signal based on temperature characteristic information relating to temperature characteristics of the frequency of the first clock signal.

It suffices that the temperature characteristic information be information relating to the temperature characteristics of the frequency of the first clock signal. For example, the temperature characteristic information may be direct information obtained from the measurement result for the temperature characteristics of the frequency of the first clock signal, or may be indirect information obtained from the measurement result for the temperature characteristics of a current that flows through the oscillation circuit or the reference voltage output from the regulator.

The temperature characteristic information may be a predetermined setting value (i.e., a setting value that brings the temperature characteristics of the frequency of the first clock signal close to a design value or the like) calculated from the measurement result for the temperature characteristics of the frequency of the first clock signal obtained when testing the integrated circuit device, for example.

The temperature characteristic information may be supplied from a nonvolatile memory provided outside the integrated circuit device, or may be stored in a nonvolatile memory provided in the integrated circuit device.

According to this embodiment, the frequency of the first clock signal output from the oscillation circuit can be controlled based on the temperature characteristics of the frequency of the first clock signal. Therefore, even if the temperature characteristics of the oscillation circuit vary due to a difference in production conditions for the integrated circuit device and the like, the oscillation circuit can be adjusted so that the temperature characteristics of the frequency of the first clock signal approach a predetermined characteristic value (e.g., design value). As a result, the correction range of the frequency of the third clock signal can be reduced so that the configuration of the clock signal generation section can be simplified.

(5) In this integrated circuit device,

the oscillation circuit may include:

a ring oscillator formed of odd-numbered stages of inverter circuits connected in series, each of the inverter circuits including an inverter element and at least one current source that supplies a current to the inverter element, and an output of a final-stage inverter circuit among the inverter circuits being connected to an input of a first-stage inverter circuit among the inverter circuits; and

a current control circuit that controls the current supplied from the current source based on a predetermined current control signal; and

the frequency control section may generate the current control signal based on the temperature characteristic information.

According to this embodiment, the oscillation frequency of the ring oscillator (i.e., the frequency of the first clock signal) can be easily controlled by controlling a current that flows through the ring oscillator based on the temperature characteristics of the frequency of the first clock signal. Therefore, even if the temperature characteristics of the oscillation circuit vary due to a difference in production conditions for the integrated circuit device and the like, the oscillation circuit can be adjusted so that the temperature characteristics of the frequency of the first clock signal approach a predetermined characteristic value (e.g., design value). As a result, the correction range of the frequency of the third clock signal can be reduced so that the configuration of the clock signal generation section can be simplified.

(6) The integrated circuit device may further comprise:

a regulator that generates a reference voltage for driving the oscillation circuit; and

a reference voltage control section that controls the reference voltage based on temperature characteristic information relating to temperature characteristics of the frequency of the first clock signal.

The temperature characteristic information may be a predetermined setting value (i.e., a setting value that brings the temperature characteristics of the reference voltage close to a design value or the like) calculated from the measurement result for the temperature characteristics of the frequency of the first clock signal obtained when testing the integrated circuit device, for example.

According, to this embodiment, the reference voltage output from the regulator can be controlled based on the temperature characteristics of the frequency of the first clock signal. Therefore, even if the temperature characteristics of the regulator vary due to a difference in production conditions for the integrated circuit device and the like, the regulator can be adjusted so that the temperature characteristics of the reference voltage approach a predetermined characteristic value (e.g., design value). As a result, the correction range of the frequency of the third clock signal can be reduced so that the configuration of the clock signal generation section can be simplified.

Some embodiments of the invention will be described in detail below, with reference to the drawings. Note that the embodiments described below do not in any way limit the scope of the invention laid out in the claims herein. In addition, not all of the elements of the embodiments described below should be taken as essential requirements of the invention.

1. Integrated Circuit Device (Measurement System)

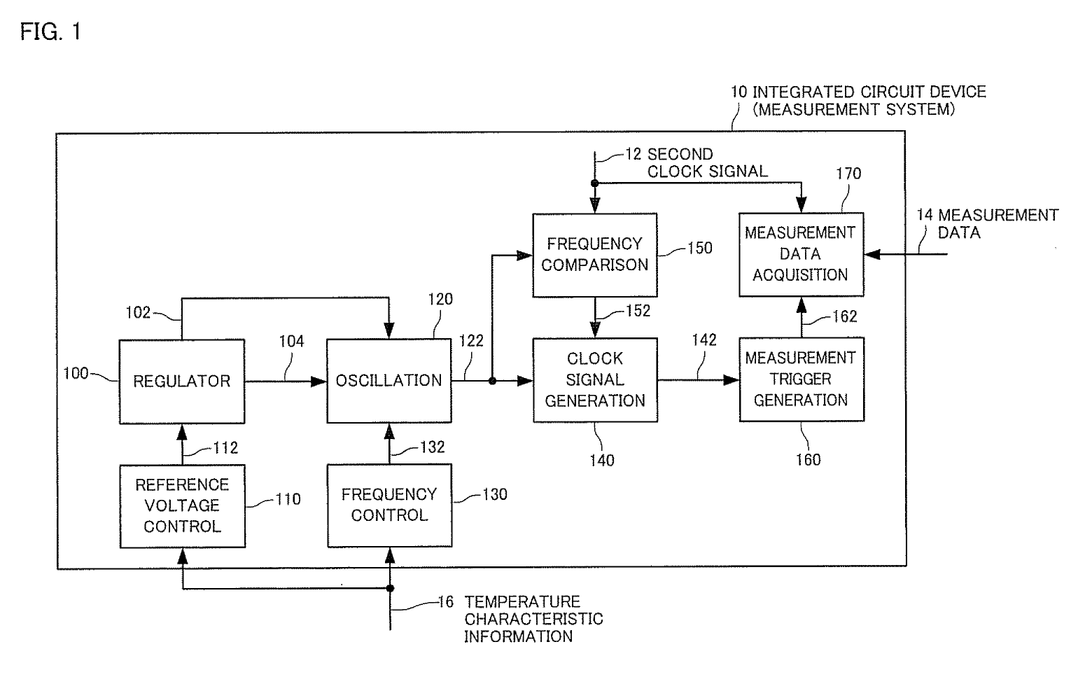

FIG. 1 is a functional block diagram showing an integrated circuit device (measurement system) according to one embodiment of the invention.

An integrated circuit device (measurement system) 10 may include a regulator 100. The regulator 100 generates a reference voltage 102 for driving an oscillation circuit 120. The regulator 100 may generate a reference current 104 for driving the oscillation circuit 120.

The integrated circuit device (measurement system) 10 may include a reference voltage control section 110. The reference voltage control section 110 controls the reference voltage 102 based on temperature characteristic information 16 relating to the temperature characteristics of the frequency of a first clock signal.

It suffices that the temperature characteristic information 16 be information relating to the temperature characteristics of the frequency of a first clock signal 122. For example, the temperature characteristic information 16 may be information directly obtained from the measurement result for the temperature characteristics of the frequency of the first clock signal 122, or may be information indirectly obtained from the measurement result for the temperature characteristics of a current that flows through the oscillation circuit 120 or the reference voltage output from the regulator.

The temperature characteristic information 16 may be a predetermined setting value (i.e., a setting value that brings the temperature characteristics of the reference voltage 102 close to a design value or the like) calculated from the measurement result for the temperature characteristics of the frequency of the first clock signal 122 obtained when testing the integrated circuit device (measurement system) 10, for example.

The temperature characteristic information 16 may be supplied from a nonvolatile memory provided outside the integrated circuit device (measurement system) 10, or may be stored in a nonvolatile memory provided in the integrated circuit device (measurement system) 10.

The integrated circuit device (measurement system) 10 includes the oscillation circuit 120. The oscillation circuit 120 generates the first clock signal 122.

The integrated circuit device (measurement system) 10 may include a frequency control section 130. The frequency control section 130 controls the frequency of the first clock signal 122 based on the temperature characteristic information 16. For example, the frequency control section 130 may generate a frequency control signal 132 to control the frequency of the first clock signal 122.

The temperature characteristic information 16 may be a predetermined setting value (i.e., a setting value that brings the temperature characteristics of the frequency of the first clock signal 122 close to a design value or the like) calculated from the measurement result for the temperature characteristics of the frequency of the first clock signal 122 obtained when testing the integrated circuit device (measurement system) 10, for example.

The integrated circuit device (measurement system) 10 may include a clock signal generation section 140. The clock signal generation section 140 generates a third clock signal 142 based on the first clock signal 122. The clock signal generation section 140 corrects the frequency of the third clock signal 142 to be a value within a predetermined range based on a comparison result 152 of a frequency comparison section 150. For example, the clock signal generation section 140 may correct the frequency of the third clock signal 142 to be a frequency within a predetermined error range with respect to a target frequency based on the comparison result 152 from the frequency comparison section 150.

The integrated circuit device (measurement system) 10 includes the frequency comparison section 150. The frequency comparison section 150 compares the frequency of the first clock signal 122 with the frequency of a second clock signal 12. The frequency comparison section 150 may compare the frequency of the first clock signal 122 with the frequency of the second clock signal 12 either directly or indirectly. For example, the frequency comparison section 150 may indirectly compare the frequency of the first clock signal 122 with the frequency of the second clock signal 12 by comparing the duration of a period defined based on the first clock signal 122 with the duration of a period defined based on the second clock signal 12.

The second clock signal 12 may be supplied from the outside of the integrated circuit device (measurement system) 10, or may be generated in the integrated circuit device (measurement system) 10. The second clock signal 12 may be supplied intermittently. The second clock signal 12 affects the correction accuracy of the frequency of the third clock signal 142. Therefore, it is preferable that the second clock signal 12 has high frequency accuracy. It is more preferable that the frequency of the second clock signal 12 changes to only a small extent due to a change in environment (e.g., a change in temperature). The second clock signal 12 may be a clock signal output from a crystal oscillator or a CR oscillation circuit, for example.

The frequency comparison section 150 may count a predetermined period defined based on the second clock signal 12, based on the first clock signal 122. The frequency comparison section 150 may count a predetermined period defined based on the second clock signal 12 directly based on the first clock signal 122, or may count a predetermined period defined based on the second clock signal 12 based on a divided clock signal of the first clock signal 122 (i.e., a clock signal obtained by dividing the frequency of the first clock signal 122). A predetermined period defined based on the second clock signal 12 may be a period corresponding to one cycle or a half cycle of the second clock signal 12, or a period corresponding to one cycle or a half cycle of a divided clock signal of the second clock signal 12, for example. A period corresponding to one cycle or a half cycle of the corrected third clock signal 142 may be defined based on the second clock signal 12, for example.

The clock signal generation section 140 may divide the frequency of the first clock signal 122 based on a count result 152 of the frequency comparison section 150 to generate the third clock signal 142. For example, when the count result 152 is n (n is an integer equal to or larger than one), the clock signal generation section 140 may divide the frequency of the first clock signal 122 by a factor of n to generate the third clock signal 142, or may divide the frequency of the first clock signal 122 by a factor of m (m is an integer equal to or larger than one that differs from n) to generate the third clock signal 142.

The frequency comparison section 150 may intermittently compare the frequency of the first clock signal 122 with the frequency of the second clock signal 12. For example, the frequency comparison section may compare the frequency of the first clock signal with the frequency of the second clock signal each time a predetermined period of time has been counted based on the third clock signal (e.g., once an hour).

The frequency comparison section 150 may intermittently compare the frequency of the first clock signal 122 with the frequency of the second clock signal 12 by intermittently counting a predetermined period defined based on the second clock signal 12 based on the first clock signal 122. The frequency comparison section 150 may hold the count result 152 until the subsequent count operation is completed, and the clock signal generation section 140 may generate the third clock signal 142 based on the count result 152 held by the frequency comparison section 150.

In the integrated circuit device (measurement system) according to this embodiment, the frequency of the third clock signal 142 generated based on the first clock signal 122 output from the oscillation circuit 120 is corrected based on the second clock signal 12. Therefore, even if the accuracy of the frequency of the first clock signal 122 is low, the frequency of the third clock signal 142 can be corrected with high accuracy when the accuracy of the frequency of the second clock signal 12 is high.

In the integrated circuit device (measurement system) according to this embodiment, the accuracy of the frequency of the third clock signal 142 mainly depends on the accuracy of the frequency of the second clock signal 12, but depends on the accuracy of the frequency of the first clock signal 122 to only a small extent. Therefore, the configuration of the oscillation circuit 120 that generates the first clock signal 122 can be simplified.

In the integrated circuit device (measurement system) according to this embodiment, the frequency of the first clock signal 122 outputted from the oscillation circuit 120 need not be corrected directly. This makes it unnecessary to provide a feedback control circuit for controlling the oscillation operation of the oscillation circuit 120.

In the integrated circuit device (measurement system) according to this embodiment, the number of cycles of the first clock signal 122 corresponding to a predetermined period defined based on the second clock signal 12 may be counted directly or indirectly, and the third clock signal 142 may be generated based on the count result 152. Therefore, the frequency of the third clock signal 142 can be corrected with the accuracy of the frequency of the second clock signal 12.

In the integrated circuit device (measurement system) according to this embodiment, a predetermined period defined based on the second clock signal 12 may be counted based on the first clock signal 122. Therefore, even if the frequency of the second clock signal 12 is higher than the frequency of the first clock signal 122, a predetermined period defined based on the second clock signal 12 can be counted based on the first clock signal 122 by setting a predetermined period defined based on the second clock signal 12 to be longer than one cycle of the first clock signal 122.

In the integrated circuit device (measurement system) according to this embodiment, the count value increases as a predetermined period defined based on the second clock signal 12 increases. Therefore, the accuracy of the frequency of the third clock signal 142 corrected based on the second clock signal 12 can be improved.

In the integrated circuit device (measurement system) according to this embodiment, the frequency of the third clock signal can be corrected by a simple configuration (i.e., counter circuit and frequency divider circuit).

In the integrated circuit device (measurement system) according to this embodiment, the frequency comparison section 150 may intermittently perform the comparison operation. Therefore, the number of comparison operations performed by the frequency comparison section 150 can be reduced so that the supply of the second clock signal 12 can be stopped when the comparison operation is not performed. As a result, current consumption can be significantly reduced Therefore, the integrated circuit device can be battery-driven for a long time even if the frequency of the second clock signal 12 is high.

In the integrated circuit device (measurement system) according to this embodiment, the frequency of the first clock signal 122 outputted from the oscillation circuit 120 may be controlled based on the temperature characteristics of the frequency of the first clock signal 122. Therefore, even if the temperature characteristics of the oscillation circuit 120 vary due to a difference in production conditions for the integrated circuit device (measurement system) and the like, the oscillation circuit 120 can be adjusted so that the temperature characteristics of the frequency of the first clock signal 122 approach a predetermined characteristic value (e.g., design value).

In the integrated circuit device (measurement system) according to this embodiment, the reference voltage 102 output from the regulator 100 can be controlled based on the temperature characteristics of the frequency of the first clock signal 122. Therefore, even if the temperature characteristics of the regulator 100 vary due to a difference in production conditions for the integrated circuit device (measurement system) and the like, the regulator 100 can be adjusted so that the temperature characteristics of the reference voltage 102 approach a predetermined characteristic value (e.g., design value). As a result, the correction range of the frequency of the third clock signal 142 can be reduced so that the configuration of the clock signal generation section 140 can be simplified.

The integrated circuit device (measurement system) 10 may include a measurement trigger generation section 160. The measurement trigger generation section 160 counts a predetermined timing based on the third clock signal 142, and generates a measurement trigger signal 162 when the predetermined timing has been reached.

The integrated circuit device (measurement system) 10 may include a measured data acquisition section 170. The measured data acquisition section 170 acquires measured data 14 in a predetermined measurement period each time the measurement trigger signal 162 is generated. The measured data acquisition section 170 determines the measurement period based on the second clock signal 12.

In the integrated circuit device (measurement system) according to this embodiment, the measured data 14 is acquired based on the second clock signal 12. Therefore, when the accuracy of the frequency of the second clock signal 12 is high and a change in the frequency of the second clock signal 12 due to a change in environment is small, the measured data 14 with high accuracy can be acquired by determining the measurement period based on the second clock signal 12 when an error in the measurement period affects the accuracy of the measured data 14, for example.

In the integrated circuit device (measurement system) according to this embodiment, the frequency of the third clock signal 142 is corrected based on the second clock signal 12 at predetermined time intervals counted based on the third clock signal 142. Therefore, when the accuracy of the frequency of the second clock signal 12 is high and a change in the frequency of the second clock signal 12 due to a change in environment is small, the third clock signal 142 is corrected to have a constant frequency with relatively high accuracy at predetermined time intervals. This improves the accuracy of the measurement time interval counted based on the third clock signal 142.

Moreover, the current consumption of the integrated circuit device (measurement system) 10 can be significantly reduced by intermittently supplying the second clock signal 12 only in the measurement period.

The reference voltage control section 110, the frequency control section 130, the clock signal generation section 140, the frequency comparison section 150, the measurement trigger generation section 160, and the measured data acquisition section 170 may be implemented by dedicated hardware, or the functions of the reference voltage control section 1 10, the frequency control section 130, the clock signal generation section 140, the frequency comparison section 150, the measurement trigger generation section 160, and the measured data acquisition section 170 may be implemented by a general-purpose CPU reading out a software.

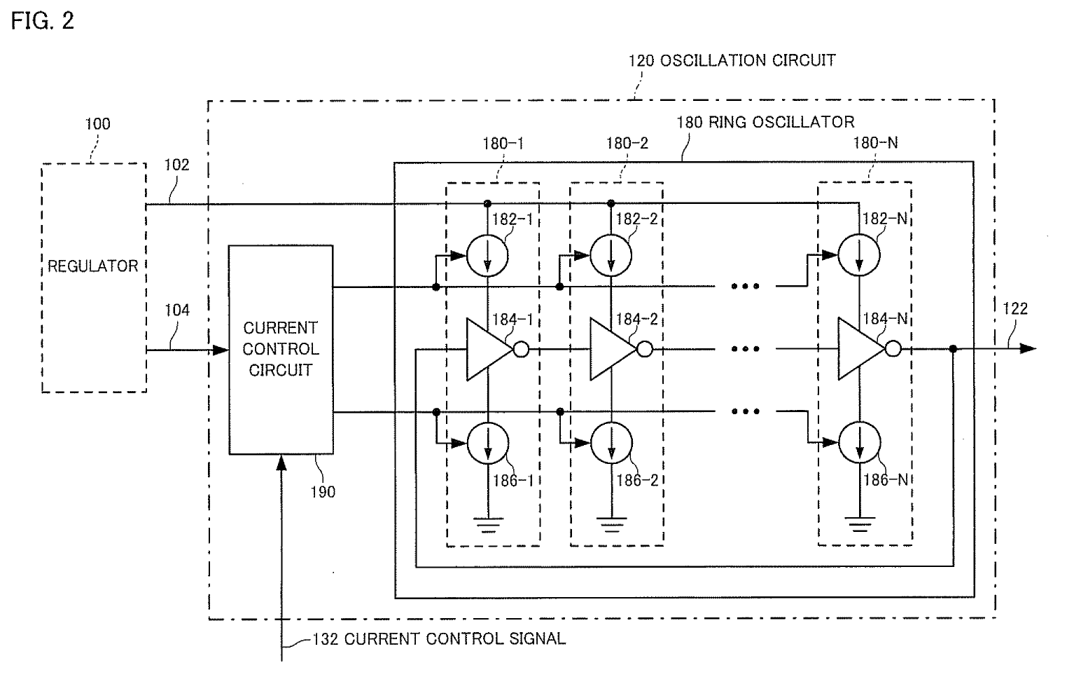

FIG. 2 is a diagram illustrative of a configuration example of the oscillation circuit included in the integrated circuit device (measurement system) according to this embodiment.

The oscillation circuit 120 includes a ring oscillator 180 and a current control circuit 190.

The ring oscillator 180 includes N stages (N is an odd number) of inverter circuits 180-1 to 180-N connected in series, the output of the final-stage inverter circuit 180-N being connected to the input of the first-stage inverter circuit 180-1. The inverter circuit 180-k (k is an integer from 1 to N) includes an inverter element 184-k and current sources 182-k and 186-k.

The current source 182-k is connected between a supply line for the reference voltage 102 output from the regulator 100 and a source terminal of a P-channel MOS transistor (not shown) that forms the inverter element 184-k. The current source 186-k is connected between a ground line and a source terminal of an N-channel MOS transistor (not shown) that forms the inverter element 184-k. The current source 182-k and the current source 186-k supply a current (e.g.) 100 nA) to the inverter element 184-k.

The current control circuit 190 controls a current supplied by the current sources 182-1 to 182-N and 186-1 to 186-N based on a current control signal 132. The current control circuit 190 may mirror a predetermined current generated based on the reference current 104 output from the regulator 100, and cause the predetermined current to flow through the current sources 182-1 to 182-N and 186-1 to 186-N, for example. The oscillation frequency of the ring oscillator 180 increases as the amount of current supplied to the inverter elements 180-1 to 180-N from the current sources 182-1 to 182-N and 186-1 to 186-N increases. Specifically, the oscillation frequency of the ring oscillator 180 can be controlled by controlling the amount of current supplied from the current sources 182-1 to 182-N and 186-1 to 186-N.

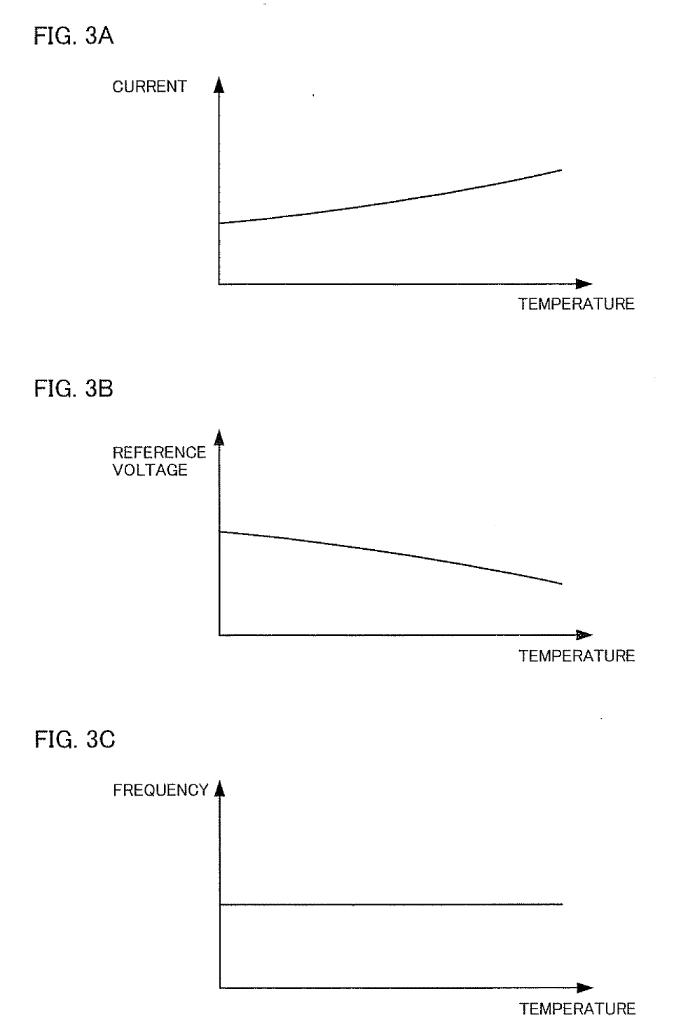

As shown in FIG. 3A, the amount of current that flows through the inverter circuits 180-1 to 180-N increases along with an increase in temperature due to the characteristics of transistors that form the inverter elements 184-1 to 184-N and the current sources 182-1 to 182-N and 186-1 to 186-N. As a result, the oscillation frequency of the ring oscillator 180 (i.e., the frequency of the first clock signal 122) increases along with an increase in temperature. Specifically, the oscillation frequency of the ring oscillator 180 (i.e., the frequency of the first clock signal 122) varies due to a change in temperature.

On the other hand, the amount of current that flows through the inverter circuits 180-1 to 180-N decreases as the reference voltage 102 decreases. Therefore, a change in the amount of current that flows through the inverter circuits 180-1 to 180-N due to a change in temperature can be reduced by forming the regulator 100 to have temperature characteristics in which the reference voltage decreases along with an increase in temperature, as shown in FIG. 3B, for example. As a result, a change in the oscillation frequency of the ring oscillator 180 (i.e., the frequency of the first clock signal 122) due to a change in temperature can be reduced, as shown in FIG. 3C.

Therefore, it is desirable to design the regulator 100 and the ring oscillator 180 so that the temperature characteristics of the reference voltage 102 are the reverse of the temperature characteristics of the amount of current that flows through the inverter circuits 180-1 to 180-N.

The characteristics of the regulator 100 and the ring oscillator 180 vary due to a difference in production conditions and the like. The characteristics of the regulator 100 and the ring oscillator 180 can be adjusted by the reference voltage control section 110 and the frequency control section 130 described with reference to FIG. 1 corresponding to each IC so that a change in the oscillation frequency of the ring oscillator 180 (i.e., the frequency of the first clock signal 122) due to a change in temperature is minimized.

In the integrated circuit device (measurement system) according to this embodiment, the oscillation frequency of the ring oscillator 180 (i.e., the frequency of the first clock signal 122) can be easily controlled by controlling a current that flows through the ring oscillator 180 based on the temperature characteristics of the frequency of the first clock signal 122.

However, since measures such as increasing the adjustment accuracy are required in order to minimize a change in the oscillation frequency of the ring oscillator 180 (i.e., the frequency of the first clock signal 122) due to a change in temperature, the circuit scale increases. Therefore, even if the oscillation frequency of the ring oscillator 180 (i.e., the frequency of the first clock signal 122) changes to some extent due to a change in temperature as a result of relatively reducing the adjustment accuracy, the frequency of the third clock signal 142 is corrected based on the second clock signal 12 by the clock signal generation section 140 described with reference to FIG. 1. If a change in the frequency of the second clock signal 12 due to a change in an environmental factor such as temperature is very small, a change in the frequency of the third clock signal 142 can be reduced.

Moreover, the correction range of the frequency of the third clock signal 142 can be reduced by making an adjustment in advance corresponding to each IC so that a change in the frequency of the first clock signal 122 due to a change in temperature is minimized, whereby the configuration of the clock signal generation section 140 can be simplified. Specifically, the integrated circuit device (measurement system) according to this embodiment enables a change in the frequency of the third clock signal 142 to be significantly reduced at low cost.

If a change in the frequency of the third clock signal 142 is small, the third clock signal 142 with low current consumption can always be supplied as the operation clock signal of the measurement trigger generation section 160 described with reference to FIG. 1. Since it suffices that the second clock signal 12 be intermittently supplied only in the acquisition period of the measured data 14 and the frequency correction period, current consumption can be significantly reduced.

Specifically, the integrated circuit device (measurement system) according to this embodiment can significantly reduce power consumption by forming the oscillation circuit 120 using the ring oscillator 180 with low current consumption, and intermittently supplying the second clock signal 12 while always generating the third clock signal 142. In this case, since the frequency of the third clock signal 142 is also intermittently corrected, it is desirable to correct the frequency of the third clock signal 142 at time intervals that ensure that a change in environment from the preceding frequency correction to the current frequency correction is small.

In the configuration shown in FIG. 2, the output from the final-stage inverter circuit 180-N is used as the first clock signal. Note that the output from an arbitrary inverter circuit 180-k may be used as the first clock signal.

2. Fire Alarm System

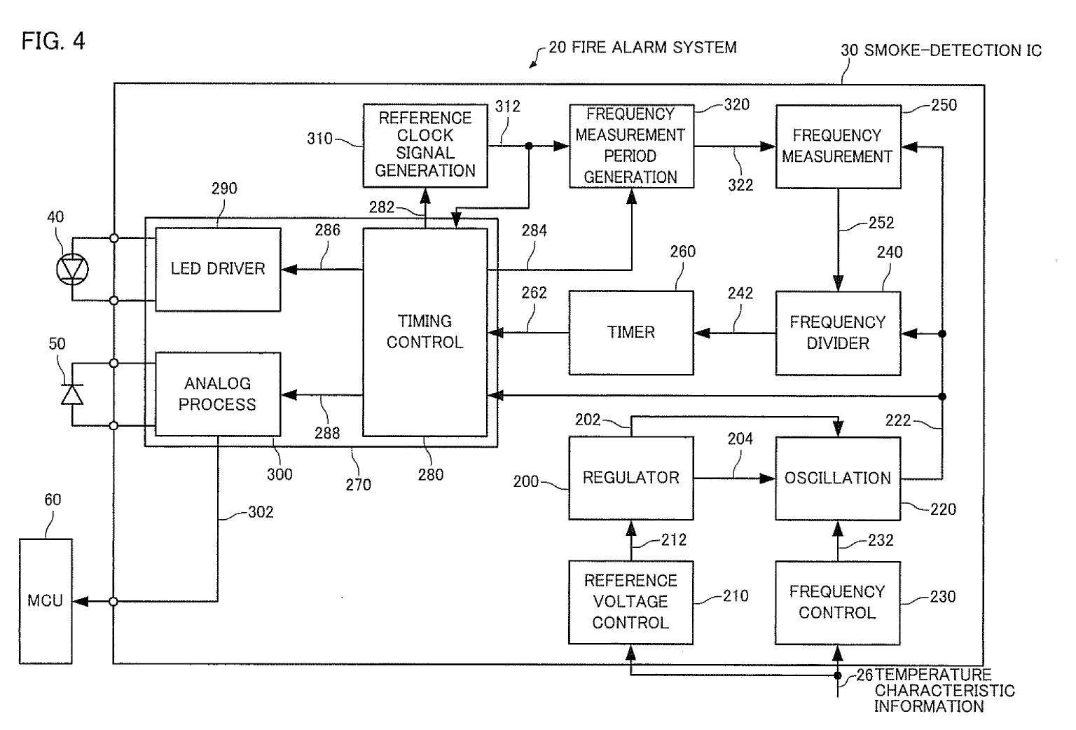

FIG. 4 is a block diagram showing a fire alarm system according to one embodiment of the invention.

A fire alarm system 20 includes a smoke-detection IC 30, a light-emitting diode (LED) 40 (i.e., light-emitting element), a photodiode 50 (i.e., light-receiving element), and a microcomputer unit (MCU) 60.

The smoke-detection IC 30 causes the LED 40 to emit light for a predetermined period of time (e.g., 90 microseconds) at predetermined time intervals (e.g., at intervals of eight seconds), and detects the amount of current that flows through the photodiode 50. Since a current proportional to the amount of received light flows through the photodiode 50, the amount of current that flows through the photodiode 50 decreases when the amount of light received by the photodiode 50 decreases due to smoke caused by fire or the like. The smoke-detection IC 30 converts the detected amount of current into an analog voltage value, and outputs the analog voltage value. The MCU 60 stores data obtained by A/D-converting the analog voltage value output from the smoke-detection IC 30, and determines whether or not fire has occurred from a transition in data up to the present time and the like.

The integrated circuit device (measurement system) described with reference to FIG. 1 may be applied as the smoke-detection IC 30. The configuration of the smoke-detection IC 30 is described in detail below.

The smoke-detection IC 30 includes a regulator 200, a reference voltage control circuit 210, an oscillation circuit 220, a frequency control circuit 230, a frequency divider circuit 240, a frequency measurement circuit 250, a timer 260, a timing control circuit 280, an LED driver circuit 290, an analog process circuit 300, a reference clock generator 310, and a frequency measurement period generation circuit 320.

The regulator 200 generates a predetermined reference voltage 202 and a predetermined reference current 204 necessary for the oscillation operation of the oscillation circuit 220. The regulator 200 corresponds to the regulator 100 described with reference to FIG. 1.

The reference voltage control circuit 210 generates a reference voltage control signal 212 based on temperature characteristic information 26 relating to the temperature characteristics of the frequency of a master clock signal 222, and adjusts a variation in the characteristics of the regulator 200 so that the predetermined reference voltage 202 is output from the regulator 200. The reference voltage control circuit 210 corresponds to the reference voltage control section 110 described with reference to FIG. 1.

The oscillation circuit 220 mirrors the reference current 204 output from the regulator 200 to cause a predetermined constant current (e.g., 100 nA) to flow through the oscillation circuit 220, and generates the master clock signal 222 having a predetermined frequency (e.g., 40 kHz).

The oscillation circuit 220 may include a ring oscillator that includes odd-numbered stages of inverter circuits connected in series, each of the inverter circuits including an inverter element and at least one current source that supplies a current to the inverter element, the output of the final-stage inverter circuit being connected to the input of the first-stage inverter circuit, for example. In this case, only a small amount of current (e.g., several hundreds of nA) flows through the oscillation circuit 220, although the amount of current varies depending on the number of stages of the ring oscillator. Therefore, current consumption is very small even if the oscillation circuit 220 always performs the oscillation operation. The oscillation circuit 220 corresponds to the oscillation circuit 120 described with reference to FIGS. 1 and 2. The master clock signal 222 corresponds to the first clock signal 122 described with reference to FIG. 1.

The frequency control circuit 230 generates a frequency control signal 232 based on the temperature characteristic information 26, and adjusts a variation in the characteristics of the oscillation circuit 220 so that the master clock signal 222 having a predetermined frequency (e.g., 40 kHz) is generated. The frequency control circuit 230 corresponds to the frequency control section 130 described with reference to FIG. 1.

The reference clock signal generation circuit 310 generates a reference clock signal 312 only when a reference clock signal enable signal 282 is set in an enabled state. The reference clock signal generation circuit 310 includes a CR oscillation circuit, for example. The reference clock signal generation circuit 310 generates the reference clock signal 312 having a constant frequency (e.g., 1 MHz) that varies to only a small extent depending on the temperature. The reference clock signal 312 corresponds to the second clock signal 12 described with reference to FIG. 1.

When a frequency correction trigger signal 284 has been generated, the frequency measurement period generation circuit 320 generates a frequency measurement period definition signal 322 that defines a predetermined measurement period based on the reference clock signal 312. For example, the frequency measurement period generation circuit 320 counts the reference clock signal 312 having a frequency of 1 MHz corresponding to 250 clock cycles, and generates the frequency measurement period definition signal 322 that is set at the H level for 250 microseconds. The frequency correction trigger signal 284 is generated by the timing control circuit 280, and indicates the timing at which the frequency of a divided clock signal 242 is corrected.

The frequency measurement circuit 250 measures the number of clock cycles of the master clock signal 222 corresponding to the measurement period defined by the frequency measurement period definition signal 322, and outputs a frequency measurement result 252. For example, when the measurement period is 250 microseconds and the oscillation frequency of the master clock signal 222 is 40 kHz, the frequency measurement result 252 is 10 (=250 microseconds×40 kHz). The frequency measurement circuit 250 corresponds to the frequency comparison section 150 described with reference to FIG, 1.

The frequency divider circuit 240 generates the divided clock signal 242 of the master clock signal 222 using the frequency measurement result 252 of the frequency measurement circuit 250 as the dividing ratio. For example, when the measurement period is 250 microseconds and the oscillation frequency of the master clock signal 222 is 40 kHz (i.e., the frequency measurement result 252 is 10), the frequency of the master clock signal 222 is divided by a factor of 10 to generate the divided clock signal 242 having a frequency of 4 kHz. The frequency divider circuit 240 corresponds to the clock signal generation section 140 described with reference to FIG. 1. The divided clock signal 242 corresponds to the third clock signal 142 described with reference to FIG. 1.

Since the frequency measurement result 252 of the frequency measurement circuit 250 has an error of up to about one clock cycle of the master clock signal 222, one cycle of the divided clock signal 242 also has an error of up to about one clock cycle of the master clock signal 222. For example, when the oscillation frequency of the master clock signal 222 is 40 kHz and the measurement period is 250 microseconds, the frequency measurement result 252 is 9, 10, or 11. In this case, the cycle of the divided clock signal 242 has an error of up to about 10%.

The timer 260 counts a predetermined period of time (e.g., eight seconds) based on the divided clock signal 242, and outputs a measurement trigger signal 262 each time the predetermined period of time has elapsed. The timer 260 corresponds to the measurement trigger generation section 160 described with reference to FIG. 1.

A measured data acquisition circuit 270 includes the timing control circuit 280, the LED driver circuit 290, and the analog process circuit 300. The measured data acquisition circuit 270 corresponds to the measured data acquisition section 170 described with reference to FIG. 1.

The timing control circuit 280 generates the reference clock signal enable signal 282, the frequency correction trigger signal 284, an LED drive signal 286, and an analog process enable signal 288.

The LED driver circuit 290 causes the LED 40 to emit light when the LED drive signal 286 is set in a drive state (e.g., H level). The LED driver circuit 290 may be implemented by a transistor switch circuit that is turned ON/OFF based on the LED drive signal 286, for example. The LED driver circuit 290 functions as a light-emitting element drive control section.

The analog process circuit 300 converts a current that flows through the photodiode 50 into a voltage, amplifies the voltage, and outputs measured data 302 to the outside. The analog process circuit 300 functions as a received light data acquisition section.

The regulator 200, the reference voltage control circuit 210, the oscillation circuit 220, the frequency control circuit 230, the frequency divider circuit 240, the frequency measurement circuit 250, the timer 260, the timing control circuit 280, the LED driver circuit 290, the analog process circuit 300, the reference clock signal generation circuit 310, and the frequency measurement period generation circuit 320 need not necessarily be included in one IC (smoke-detection IC 30), but may be separately provided in a plurality of ICs. The function of the MCU 60 may be implemented in the smoke-detection IC 30.

In the fire alarm system according to this embodiment, the measurement trigger signal 262 is generated based on the divided clock signal 242 generated based on the master clock signal 222. Therefore, when the current consumption of the oscillation circuit 220 that generates the master clock signal 222 is low, current consumption in a non-measurement period can be reduced.

In the fire alarm system according to this embodiment, the light-on time of the LED 40 is controlled based on the reference clock signal 312. Therefore, since the light-on time of the LED 40 can be accurately controlled when the accuracy of the frequency of the reference clock signal 312 is high, the accuracy of the measured data 302 can be improved.

The reference clock signal 312 may be supplied intermittently. In the fire alarm system according to this embodiment, the reference clock signal 312 need not be generated in a period (non-measurement period) in which the reference clock signal 312 is unnecessary. As a result, current consumption can be reduced. Therefore, the fire alarm system can be battery-driven for a long time even if the frequency of the second clock signal is high.

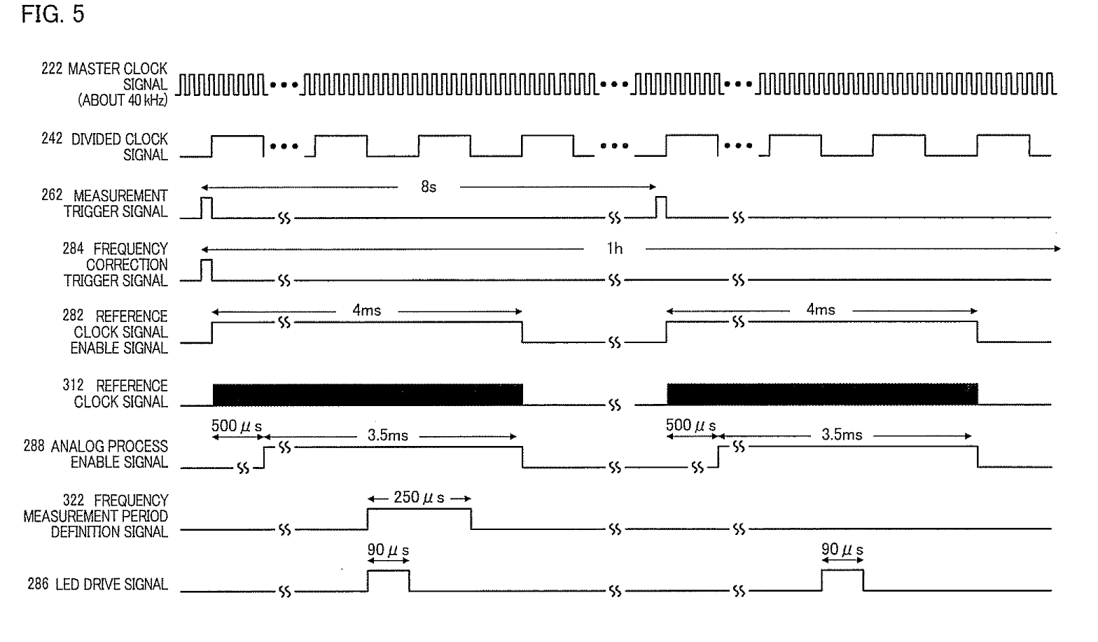

FIG. 5 is a timing chart illustrative of an example of the operation timing of the smoke-detection IC (integrated circuit device (measurement system) according to this embodiment) included in the fire alarm system according to this embodiment described with reference to FIG. 4. The timing chart shown in FIG. 5 is described below with reference to FIG. 4.

The master clock signal 222 is a clock signal having a frequency of about 40 kHz, for example. The master clock signal 222 is always generated by the oscillation operation of the oscillation circuit 220 Since the characteristics of the regulator 200 and the oscillation circuit 220 change depending on the temperature, the frequency of the master clock signal 222 changes depending on the temperature.

The divided clock signal 242 is generated by causing the frequency divider circuit 240 to divide the frequency of the master clock signal 222 at a dividing ratio (e.g., 10) corresponding to the frequency measurement result 252 (e.g., 10).

The measurement trigger signal 262 is generated by the timer 260 as an H pulse signal at intervals of about eight seconds, for example. The generation cycle (about eight seconds) of the measurement trigger signal 262 is counted based on the divided clock signal 242. Therefore, the generation cycle of the measurement trigger signal 262 has an error due to an error in the frequency of the divided clock signal 242.

For example, the number of measurements unnecessarily increases as the generation cycle of the measurement trigger signal 262 decreases Therefore, the current consumption of the smoke-detection IC 30 increases. For example, since the measurement interval increases as the Generation cycle of the measurement trigger signal 262 increases, the MCU 60 may determine occurrence of fire after a delay. Therefore, it is desirable that the frequency of the divided clock signal 242 has an error within a predetermined allowable range (e.g., ±10%).

The frequency correction trigger signal 284 is generated by the timing control circuit 280 as an H pulse signal at intervals corresponding to 450 measurement trigger signals 262 that are generated at intervals of about eight seconds (i.e., about every hour), for example. The generation cycle (about one hour) of the frequency correction trigger signal 284 is counted based on the divided clock signal 242.

The frequency correction trigger signal 284 indicates the timing at which the frequency of the divided clock signal 242 is corrected. Therefore, the frequency correction interval decreases as the generation cycle of the frequency correction trigger signal 284 decreases so that the frequency of the divided clock signal 242 can be promptly corrected even if a rapid change in temperature has occurred. On the other hand, current consumption increases. The frequency correction interval increases as the generation cycle of the frequency correction trigger signal 284 increases so that current consumption decreases. On the other hand, the frequency of the divided clock signal 242 may not be promptly corrected when a rapid chance in temperature has occurred.

Therefore, it is desirable to appropriately select the generation cycle of the frequency correction trigger signal 284 taking a change in temperature and the like into account. For example, the ambient temperature is regularly detected so that the generation cycle of the frequency correction trigger signal 284 is changed corresponding to the change in temperature.

The reference clock signal enable signal 282 is controlled by the timing control circuit 280 SO that the reference clock signal enable signal 282 is set in an enabled state (e.g., H level) for four milliseconds after the measurement trigger signal 262 has been generated, for example. The period of time (four milliseconds) in which the reference clock signal enable signal 282 is set in an enabled state may be counted by the timing control circuit 280 based on the reference clock signal 312 or the divided clock signal 242.

The reference clock signal 312 has a frequency of 1 MHz, for example. The reference clock signal 312 is generated by the reference clock signal generation circuit 310 when the reference clock signal enable signal 282 is set in an enabled state (four milliseconds). The reference clock signal 312 is fixed at the L level when the reference clock signal enable signal 282 is not set in an enabled state (L level period (about 7.996 seconds) within about eight seconds), for example. The period of time in which the reference clock signal 312 is generated (i.e., the reference clock signal generation circuit 310 performs the oscillation operation) is four milliseconds within about eight seconds. Therefore, the power consumption of the reference clock signal generation circuit 310 and the circuit that operates based on the reference clock signal 312 can be significantly reduced.

The analog, process enable signal 288 is controlled by the timing control circuit 280 so that the analog process enable signal 288 is set in an enabled state (H level) for 3.5 milliseconds after 500 microseconds has elapsed after the reference clock signal enable signal 282 has been set in an enabled state (H level), for example. The period of time (500 microseconds) until the analog process enable signal 288 is set in an enabled state and the period of time (3.5 milliseconds) in which the analog process enable signal 288 is set in an enabled state may be counted by the timing control circuit 280 based on the reference clock signal 312 or the divided clock signal 242.

The frequency measurement period definition signal 322 is controlled by the timing control circuit 280 so that the frequency measurement period definition signal 322 is set at the H level for 250 microseconds when the reference clock signal enable signal 282 is set in an enabled state (H level), for example. The period of time (250 microseconds) in which the frequency measurement period definition signal 322 is set at the H level is counted by the timing control circuit 280 based on the reference clock signal 312.

The LED drive signal 286 is controlled by the timing control circuit 280 so that the LED drive signal 286 is set in a drive state (H level) for 90 microseconds when the reference clock signal enable signal 282 is set in an enabled state (H level), for example. The period of time (90 microseconds) in which the LED drive signal 286 is set in a drive state is counted by the timing control circuit 280 based on the reference clock signal 312.

The LED 40 emits light for 90 microseconds when the LED drive signal 286 is set in a drive state (e.g., H level) (i.e., at intervals of about eight seconds). A current corresponding to the amount of light received by the photodiode 50 when the LED 40 emits light is detected by the analog process section 300. The measured data 302 is updated and output every eight seconds. The MCU 60 determines the presence or absence of smoke from the history of the measured data 302 that is regularly updated.

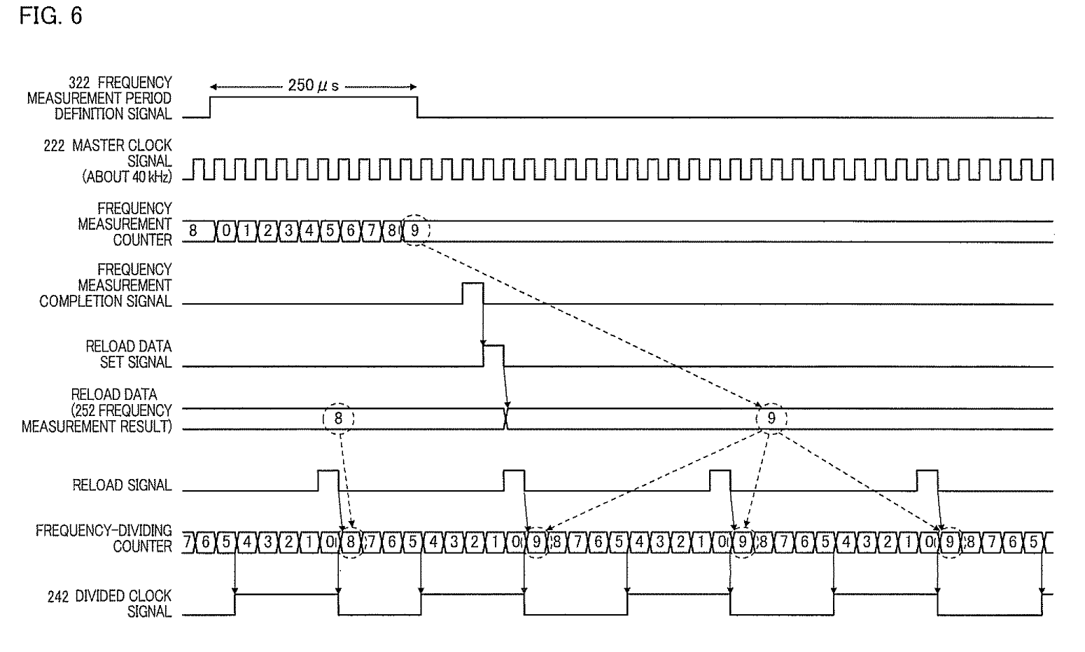

FIG. 6 is a timing chart illustrative of an example of the operation timing of the frequency measurement circuit and the timer included in the smoke-detection IC shown in FIG. 4. The timing chart shown in FIG. 6 is described below with reference to FIG. 4.

The H level period (about 250 microseconds) of the frequency measurement period definition signal 322 generated based on the reference clock signal 312 is counted by a predetermined frequency measurement counter based on the master clock signal 222 (about 40 kHz). For example, the frequency measurement counter is provided in the frequency measurement circuit 250.

The measurement of the frequency of the master clock signal 222 is completed when the frequency measurement period definition signal 322 has changed to the L level from the H level, and a frequency measurement completion signal (H pulse) is generated. A reload data set signal (H pulse) is then generated. The output from the frequency measurement counter is held as reload data (frequency measurement result 252) at the generation timing of the reload data set signal.

For example, when the frequency measurement result 252 obtained by the preceding frequency measurement (about one hour ago) is eight and the measurement counter has counted from 0 to 9 in the current frequency measurement, the frequency measurement result 252 is updated to nine.

The frequency divider circuit 240 includes a predetermined frequency-dividing counter that operates based on the master clock signal 222 in order to generate the divided clock signal 242, for example. The frequency-dividing counter is formed as a down-counter, for example. A reload signal (H pulse) is generated each time the count value has reached zero so that the reload data (frequency measurement result 252) is reloaded to the frequency-dividing counter.

The divided clock signal 242 is generated so that the divided clock signal 242 changes from the L level to the H level when the output from the frequency-dividing counter is five, and changes from the H level to the L level when the output from the frequency-dividing counter is zero, for example. Therefore, the divided clock signal 242 is corrected so that the cycle between the rising edges of the divided clock signal 242 coincides with the frequency measurement period (i.e., a period in which the frequency measurement period definition signal 322 is set at the H level).

In the timing chart shown in FIG. 6, the frequency measurement result 252 has changed from eight to nine due to a change in environment (e.g., temperature) during the preceding frequency measurement (about one hour ago) and the current frequency measurement, for example. Specifically, while one cycle of the divided clock signal obtained by dividing the frequency of the master clock signal 222 by a factor of nine is about 250 microseconds during the preceding frequency measurement (about one hour ago), one cycle of the divided clock signal obtained by dividing the frequency of the master clock signal 222 by a factor of ten is also about 250 microseconds during the current frequency measurement.

Hence, in the integrated circuit device, the measurement system, or the fire alarm system according to this embodiment, the average value of the frequencies of the divided clock signal 242 is kept almost constant even if the frequency of the master clock signal 222 has changed due to a change in environment (e.g., temperature). As a result, the average value of the generation intervals of the measurement trigger signal 262 is also kept almost constant (e.g., about eight seconds). Therefore, the average value of the light-on intervals of the LED 40 can be kept constant (about eight seconds) by causing the oscillation circuit 220 with low power consumption to always operate while minimizing the operation period (timing) of the reference clock signal generation circuit 310 that generates a highly accurate reference clock signal, but consumes a large amount of power.

In the integrated circuit device, the measurement system, or the fire alarm system according to this embodiment, the reference clock signal 312 is generated for only four milliseconds when the reference clock signal enable signal 282 is set in an enabled state each time the measurement trigger signal 262 is generated at intervals of eight seconds, for example. Therefore, the integrated circuit device, the measurement system, or the fire alarm system can operate with significantly reduced power consumption.

Note that the invention is not limited to the above-described embodiments. Various modifications and variations may be made without departing from the scope of the invention.

In the timing chart shown in FIG. 5, the measurement trigger signal 262 and the frequency correction trigger signal 284 are H pulse signals. Note that the measurement trigger signal 262 and the frequency correction trigger signal 284 may be L pulse signals.

In the timing chart shown in FIG. 5, the reference clock signal enable signal 282, the analog process enable signal 288, the frequency measurement period definition signal 322, and the LED drive signal 286 are set in an enabled state or a drive state when set at the H level. Note that the reference clock signal enable signal 282, the analog process enable signal 288, the frequency measurement period definition signal 322, and the LED drive signal 286 may be set in an enabled state or a drive state when set at the L level.

Although only some embodiments of this invention have been described in detail above, those skilled in the art will readily appreciate that many modifications are possible in the embodiments without materially departing from the novel teachings and advantages of this invention. Accordingly, all such modifications are intended to be included within the scope of the invention.

What is claimed is:

1. An integrated circuit device comprising:
an oscillation circuit that generates a first clock signal;
a frequency comparison section that compares a frequency of the first clock signal with a frequency of a given second clock signal; and
a clock signal generation section that generates a third clock signal based on the first clock signal,
the clock signal veneration section correcting a frequency of the third clock signal to be a value within a predetermined range based on the comparison result of the frequency comparison section.

2. The integrated circuit device as defined in claim 1,
the frequency comparison section counting a predetermined period based on the first clock signal, the predetermined period being defined based on the second clock signal,
the clock signal generation section generating the third clock signal by frequency-dividing the first clock signal based on a count result of the frequency comparison section.

3. The integrated circuit device as defined in claim 1,
the frequency comparison section intermittently comparing the frequency of the first clock signal with the frequency of the second clock signal.

4. The integrated circuit device as defined in claim 2,
the frequency comparison section intermittently comparing the frequency of the first clock signal with the frequency of the second clock signal.

5. The integrated circuit device as defined in claim 1, further comprising:
a frequency control section that controls the frequency of the first clock signal based on temperature characteristic information relating to temperature characteristics of the frequency of the first clock signal.

6. The integrated circuit device as defined in claim 2, further comprising
a frequency control section that controls the frequency of the first clock signal based on temperature characteristic information relating to temperature characteristics of the frequency of the first clock signal.

7. The integrated circuit device as defined in claim 3, further comprising:
a frequency control section that controls the frequency of the first clock signal based on temperature characteristic information relating to temperature characteristics of the frequency of the first clock signal.

8. The integrated circuit device as defined in claim 4, further comprising
a frequency control section that controls the frequency of the first clock signal based on temperature characteristic information relating to temperature characteristics of the frequency of the first clock signal.

9. The integrated circuit device as defined in claim 5,
the oscillation circuit including:
a ring oscillator formed of odd-numbered stages of inverter circuits connected in series, each of the inverter circuits including an inverter element and at least one current source that supplies a current to the inverter element, and an output of a final-stage inverter circuit among the inverter circuits being connected to an input of a first-stage inverter circuit among the inverter circuits; and
a current control circuit that controls the current supplied from the current source based on a predetermined current control signal,
the frequency control section generating the current control signal based on the temperature characteristic information

10. The integrated circuit device as defined in claim 6,
the oscillation circuit including:
a ring oscillator formed of odd-numbered stages of inverter circuits connected in series, each of the inverter circuits including an inverter element and at least one current source that supplies a current to the inverter element, and an output of a final-stage inverter circuit among the inverter circuits being connected to an input of a first-stage inverter circuit among the inverter circuits; and
a current control circuit that controls the current supplied from the current source based on a predetermined current control signal,
the frequency control section generating the current control signal based on the temperature characteristic information.

11. The integrated circuit device as defined in claim 7,
the oscillation circuit including:
a ring oscillator formed of odd-numbered stages of inverter circuits connected in series, each of the inverter circuits including an inverter element and at least one current source that supplies a current to the inverter element, and an output of a final-stage inverter circuit among the inverter circuits being connected to an input of a first-stage inverter circuit among the inverter circuits; and
a current control circuit that controls the current supplied from the current source based on a predetermined current control signal,
the frequency control section generating the current control signal based on the temperature characteristic information.

12. The integrated circuit device as defined in claim 8,
the oscillation circuit including:
a ring oscillator formed of odd-numbered stages of inverter circuits connected in series, each of the inverter circuits including an inverter element and at least one current source that supplies a current to the inverter element, and an output of a final-stage inverter circuit among the inverter circuits being connected to an input of a first-stage inverter circuit among the inverter circuits; and
a current control circuit that controls the current supplied from the current source based on a predetermined current control signal,
the frequency control section generating the current control signal based on the temperature characteristic information.

13. The integrated circuit device as defined in claim 1, further comprising;
a regulator that generates a reference voltage for driving the oscillation circuit; and
a reference voltage control section that controls the reference voltage based on temperature characteristic information relating to temperature characteristics of the frequency of the first clock signal.

14. The integrated circuit device as defined in claim 2, further comprising:
a regulator that generates a reference voltage for driving the oscillation circuit; and
a reference voltage control section that controls the reference voltage based on temperature characteristic information relating to temperature characteristics of the frequency of the first clock signal.

15. The integrated circuit device as defined in claim 3, further comprising:
a regulator that generates a reference voltage for driving the oscillation circuit; and
a reference voltage control section that controls the reference voltage based on temperature characteristic information relating to temperature characteristics of the frequency of the first clock signal.

16. The integrated circuit device as defined in claim 4, further comprising:
a regulator that generates a reference voltage for driving the oscillation circuit; and
a reference voltage control section that controls the reference voltage based on temperature characteristic information relating to temperature characteristics of the frequency of the first clock signal.

17. The integrated circuit device as defined in claim 5, further comprising:
a regulator that generates a reference voltage for driving the oscillation circuit; and
a reference voltage control section that controls the reference voltage based on temperature characteristic information relating to temperature characteristics of the frequency of the first clock signal.

18. The integrated circuit device as defined in claim 6, further comprising:
a regulator that generates a reference voltage for driving the oscillation circuit; and
a reference voltage control section that controls the reference voltage based on temperature characteristic information relating to temperature characteristics of the frequency of the first clock signal

19. The integrated circuit device as defined in claim 7, further comprising:
a regulator that generates a reference voltage for driving the oscillation circuit; and
a reference voltage control section that controls the reference voltage based on temperature characteristic information relating to temperature characteristics of the frequency of the first clock signal.

20. The integrated circuit device as defined in claim 9, further comprising:
a regulator that generates a reference voltage for driving the oscillation circuit; and
a reference voltage control section that controls the reference voltage based on temperature characteristic information relating to temperature characteristics of the frequency of the first clock signal.
